(19) United States
(12) Patent Application Publication
(10) Pub. No.: US 2025/0386680 A1
(43) Pub. Date: Dec. 18, 2025

(54) DISPLAY PANEL, MANUFACTURING METHOD OF THE SAME, AND DISPLAY DEVICE

(71) Applicant: HKC CORPORATION LIMITED, SHENZHEN (CN)

(72) Inventors: Chenchen JIANG, SHENZHEN (CN); Xiufeng ZHOU, SHENZHEN (CN); Zhisheng XIE, SHENZHEN (CN); Yangling TANG, SHENZHEN (CN); Qin LIANG, SHENZHEN (CN); Zhi YANG, SHENZHEN (CN); Lidan YE, SHENZHEN (CN)

(73) Assignee: HKC CORPORATION LIMITED, SHENZHEN (CN)

(21) Appl. No.: 19/235,633

(22) Filed: Jun. 12, 2025

(30) Foreign Application Priority Data
Jun. 17, 2024 (CN) 202410782073.4

(51) Int. Cl. H10K 59/122; H10K 59/12; H10K 59/80

(52) U.S. Cl. CPC H10K 59/122; H10K 59/1201; H10K 59/873

(57) ABSTRACT

A display panel, a manufacturing method of the same, and a display device. The method includes: providing a preformed plate; and depositing and forming a light-emitting layer and a cathode on the preformed plate in sequence. The preformed plate includes a drive substrate, anodes, a pixel definition layer, and conductive isolation structures. The anodes, the light-emitting layer, and the cathode are sequentially deposited in the pixel openings to form subpixel units. Before the depositing and forming the cathode, the method further includes: vapor-depositing and forming a barrier layer on the light-emitting layer on a position except a target pixel opening, where the barrier layer is mutually repulsive with the cathode. After the depositing and forming the cathode, the method further includes: removing the barrier layer and the light-emitting layer on the position except the region of the target pixel opening.

### CROSS-REFERENCE TO RELATED APPLICATIONS

The present application claims priority of Chinese Patent Application No. 202410782073.4, filed on Jun. 17, 2024, the entire contents of which are hereby incorporated by reference in their entirety.

### TECHNICAL FIELD

The present disclosure relates to the field of display technologies, and in particular to a display panel, a manufacturing method of the same, and a display device.

### BACKGROUND

With the continuous advancement of display technologies, Electron Beam Lithography Enhanced Addressing Pixel (eLEAP) technology is poised to become one of the next-generation mass-production innovations. This technology eliminates the need for high-precision Fine Metal Masks (FMMs) during vapor-deposition, while simultaneously enhancing pixel opening ratios and pixel densities, thereby substantially improving the luminance and longevity of display products.

However, the manufacturing process of eLEAP remains highly complex. For the manufacturing process of each subpixel unit, after vapor-deposition, the cathode and organic light-emitting layer within non-target pixel openings must be selectively removed, leaving only the anode intact. This necessitates precise etching processes for both the cathode and organic layers. The procedure is not only technically intricate but also prone to partial residual cathode material due to incomplete etching, which compromises product yield and reliability.

### SUMMARY OF THE DISCLOSURE

A manufacturing method of a display panel, including:
providing a preformed plate; wherein the preformed plate includes a drive substrate, anodes, a pixel definition layer, and conductive isolation structures; the anodes and the pixel definition layer are disposed on the drive substrate, the pixel definition layer defines a plurality of pixel openings, and the anodes are disposed within the plurality of pixel openings in a one-to-one correspondence; the conductive isolation structures protrude from the pixel definition layer and surrounds the plurality of pixel openings; and
depositing and forming a light-emitting layer and a cathode on the preformed plate in sequence; wherein in each pixel opening, a corresponding anode, the light-emitting layer, and the cathode are sequentially stacked to constitute a corresponding subpixel unit, and the cathode is in contact with and electrically connected to at least corresponding one of the conductive isolation structures;
wherein the depositing and forming a light-emitting layer and a cathode on the preformed plate in sequence includes in sequence:
   depositing and forming the light-emitting layer on the preformed plate;
   vapor-depositing and forming a barrier layer on the light-emitting layer on a position except a region of a target pixel opening by means of a mask plate; wherein the barrier layer is mutually repulsive with a material of the cathode to prevent the material of the cathode from being deposited in a region of a non-target pixel opening; wherein one of the plurality of pixel openings is defined as the target pixel opening, and remaining of the plurality of pixel openings is defined as the non-target pixel opening;
   depositing and forming the cathode on the light-emitting layer; and
   removing the light-emitting layer on the position except the region of the target pixel opening, and removing the barrier layer on at least a part of the position except the region of the target pixel opening.

A display panel, manufactured by the manufacturing method as above and including:
a drive substrate;
a pixel definition layer, disposed on the drive substrate and defining a plurality of pixel openings;
conductive isolation structures, protruding from the pixel definition layer and surrounding the plurality of pixel openings; and
subpixel units, including: anodes, a light-emitting layer, and a cathode stacked in sequence disposed in the plurality of pixel openings; wherein the cathode is in contact with and electrically connected to the conductive isolation structures;
wherein the subpixel units include a first subpixel unit and a second subpixel unit that are with different emitting colors;
a barrier layer is arranged on a side of the conductive isolation structures away from the drive substate; the barrier layer is mutually repulsive with a material of the cathode to prevent the material of the cathode from being deposited on the side of the conductive isolation structures away from the drive substate.

A display device, including a circuit board and the display panel as above; wherein the circuit board is electrically coupled to the display panel.

### BRIEF DESCRIPTION OF THE DRAWINGS

To more clearly illustrate the technical solutions of the embodiments of the present disclosure, the following is a brief introduction to the drawings used in the description of the embodiments. It should be understood that the drawings described below are merely some embodiments of the present disclosure. For those skilled in the art, other drawings can be obtained without any creative effort based on these drawings.

FIG. 1 is a flowchart of a manufacturing method of a display panel according to Implementation 1 of the present disclosure.

FIG. 2 is a structural schematic view of a preformed plate according to some embodiments of the present disclosure.

FIG. 3 is a flowchart of operation S10 in the manufacturing method as illustrated in FIG. 1 according to some embodiments of the present disclosure.

FIG. 4a is a schematic diagram of an operation in the manufacturing method as illustrated in FIG. 3 according to some embodiments of the present disclosure.

FIG. 4b is a schematic diagram of another operation in the manufacturing method as illustrated in FIG. 3 according to some embodiments of the present disclosure.

FIG. 4c is a schematic diagram of further another operation in the manufacturing method as illustrated in FIG. 3 according to some embodiments of the present disclosure.

FIG. 4d is a schematic diagram of still another operation in the manufacturing method as illustrated in FIG. 3 according to some embodiments of the present disclosure.

FIG. 4e is a schematic diagram of still another operation in the manufacturing method as illustrated in FIG. 3 according to some embodiments of the present disclosure.

FIG. 4f is a schematic diagram of still another operation in the manufacturing method as illustrated in FIG. 3 according to some embodiments of the present disclosure.

FIG. 4g is a schematic diagram of still another operation in the manufacturing method as illustrated in FIG. 3 according to some embodiments of the present disclosure.

FIG. 5 is a flowchart of a manufacturing method of a display panel according to Implementation 2 of the present disclosure.

FIG. 6a is a schematic diagram of an operation in S3 in the manufacturing method as illustrated in FIG. 5 according to some embodiments of the present disclosure.

FIG. 6b is a schematic diagram of another operation in S3 in the manufacturing method as illustrated in FIG. 5 according to some embodiments of the present disclosure.

FIG. 6c is a schematic diagram of further another operation in S3 in the manufacturing method as illustrated in FIG. 5 according to some embodiments of the present disclosure.

FIG. 6d is a schematic diagram of still another operation in S3 in the manufacturing method as illustrated in FIG. 5 according to some embodiments of the present disclosure.

FIG. 6e is a schematic diagram of still another operation in S3 in the manufacturing method as illustrated in FIG. 5 according to some embodiments of the present disclosure.

FIG. 6f is a schematic diagram of still another operation in S3 in the manufacturing method as illustrated in FIG. 5 according to some embodiments of the present disclosure.

FIG. 6g is a schematic diagram of still another operation in S3 in the manufacturing method as illustrated in FIG. 5 according to some embodiments of the present disclosure.

FIG. 7 is a flowchart of a manufacturing method of a display panel according to Implementation 3 of the present disclosure.

FIG. 8a is a schematic diagram of an operation in S4 in the manufacturing method as illustrated in FIG. 7 according to some embodiments of the present disclosure.

FIG. 8b is a schematic diagram of another operation in S4 in the manufacturing method as illustrated in FIG. 7 according to some embodiments of the present disclosure.

FIG. 8c is a schematic diagram of further another operation in S4 in the manufacturing method as illustrated in FIG. 7 according to some embodiments of the present disclosure.

FIG. 8d is a schematic diagram of still another operation in S4 in the manufacturing method as illustrated in FIG. 7 according to some embodiments of the present disclosure.

FIG. 8e is a schematic diagram of still another operation in S4 in the manufacturing method as illustrated in FIG. 7 according to some embodiments of the present disclosure.

FIG. 8f is a schematic diagram of still another operation in S4 in the manufacturing method as illustrated in FIG. 7 according to some embodiments of the present disclosure.

FIG. 8g is a schematic diagram of still another operation in S4 in the manufacturing method as illustrated in FIG. 7 according to some embodiments of the present disclosure.

FIG. 9 is a flowchart of operation S24 according to some embodiments of the present disclosure.

FIG. 10a is a schematic diagram of an operation in a manufacturing process of a first subpixel unit in the manufacturing method as illustrated in FIG. 7 according to some embodiments of the present disclosure.

FIG. 10b is a schematic diagram of another operation of a manufacturing process of a first subpixel unit in the manufacturing method as illustrated in FIG. 7 according to some embodiments of the present disclosure.

FIG. 10c is a schematic diagram of further another operation of a manufacturing process of a first subpixel unit in the manufacturing method as illustrated in FIG. 7 according to some embodiments of the present disclosure.

FIG. 10d is a schematic diagram of still another operation of a manufacturing process of a first subpixel unit in the manufacturing method as illustrated in FIG. 7 according to some embodiments of the present disclosure.

FIG. 10e is a schematic diagram of still another operation of a manufacturing process of a first subpixel unit in the manufacturing method as illustrated in FIG. 7 according to some embodiments of the present disclosure.

FIG. 10f is a schematic diagram of still another operation of a manufacturing process of a first subpixel unit in the manufacturing method as illustrated in FIG. 7 according to some embodiments of the present disclosure.

FIG. 10g is a schematic diagram of still another operation of a manufacturing process of a first subpixel unit in the manufacturing method as illustrated in FIG. 7 according to some embodiments of the present disclosure.

FIG. 11a is a schematic diagram of an operation in a manufacturing process of a second subpixel unit in the manufacturing method as illustrated in FIG. 7 according to some embodiments of the present disclosure.

FIG. 11b is a schematic diagram of another operation of a manufacturing process of a second subpixel unit in the manufacturing method as illustrated in FIG. 7 according to some embodiments of the present disclosure.

FIG. 11c is a schematic diagram of further another operation of a manufacturing process of a second subpixel unit in the manufacturing method as illustrated in FIG. 7 according to some embodiments of the present disclosure.

FIG. 11d is a schematic diagram of still another operation of a manufacturing process of a second subpixel unit in the manufacturing method as illustrated in FIG. 7 according to some embodiments of the present disclosure.

FIG. 11e is a schematic diagram of still another operation of a manufacturing process of a second subpixel unit in the manufacturing method as illustrated in FIG. 7 according to some embodiments of the present disclosure.

FIG. 11f is a schematic diagram of still another operation of a manufacturing process of a second subpixel unit in the manufacturing method as illustrated in FIG. 7 according to some embodiments of the present disclosure.

FIG. 11g is a schematic diagram of still another operation of a manufacturing process of a second subpixel unit in the manufacturing method as illustrated in FIG. 7 according to some embodiments of the present disclosure.

FIG. 12a is a schematic diagram of an operation in a manufacturing process of a third subpixel unit in the manufacturing method as illustrated in FIG. 7 according to some embodiments of the present disclosure.

FIG. 12b is a schematic diagram of another operation of a manufacturing process of a third subpixel unit in the manufacturing method as illustrated in FIG. 7 according to some embodiments of the present disclosure.

FIG. 12c is a schematic diagram of further another operation of a manufacturing process of a third subpixel unit in the manufacturing method as illustrated in FIG. 7 according to some embodiments of the present disclosure.

FIG. 12d is a schematic diagram of still another operation of a manufacturing process of a third subpixel unit in the manufacturing method as illustrated in FIG. 7 according to some embodiments of the present disclosure.

FIG. 12e is a schematic diagram of still another operation of a manufacturing process of a third subpixel unit in the manufacturing method as illustrated in FIG. 7 according to some embodiments of the present disclosure.

FIG. 12f is a schematic diagram of still another operation of a manufacturing process of a third subpixel unit in the manufacturing method as illustrated in FIG. 7 according to some embodiments of the present disclosure.

FIG. 12g is a schematic diagram of still another operation of a manufacturing process of a third subpixel unit in the manufacturing method as illustrated in FIG. 7 according to some embodiments of the present disclosure.

FIG. 13 is a structural schematic view of a display device according to some embodiments of the present disclosure.

### DETAILED DESCRIPTION

The following description, in conjunction with the accompanying drawings, provides a detailed explanation of the technical solutions of the embodiments of the present disclosure.

In the following description, specific details such as specific system structures, interfaces, and technologies are provided for the purpose of explanation rather than limitation, in order to facilitate a thorough understanding of the present disclosure.

The technical solutions in the embodiments of the present disclosure will be described in detail with reference to the accompanying drawings. It should be noted that the embodiments described herein are only some of the embodiments of the present disclosure and are not intended to be exhaustive. All other embodiments obtained by those skilled in the art without making creative contributions based on the embodiments of the present disclosure are within the scope of the present disclosure.

The terms “first,” “second,” and “third” used in the present disclosure are for descriptive purposes only and should not be understood as indicating or implying relative importance or the number of technical features indicated. Therefore, features defined with “first,” “second,” or “third” may explicitly or implicitly include at least one of the features indicated. In the description of the present disclosure, “multiple” means at least two, such as two, three, etc., unless otherwise explicitly specified. All directional indications (such as up, down, left, right, front, back, etc.) in the embodiments of the present disclosure are intended solely to explain relative positions and movements of components in a specific orientation (as shown in the drawings). When the specific orientation changes, the directional indications also change accordingly. Furthermore, the terms “include” and “have,” as well as any variations thereof, are intended to cover non-exclusive inclusion. For example, a process, method, system, product, or device that includes a series of steps or units is not limited to the steps or units listed, but may optionally include steps or units not listed, or may optionally include other steps or units inherent to such process, method, product, or device.

The term “embodiment” as used herein means that the specific features, structures, or characteristics described in connection with an embodiment may be included in at least one embodiment of the present disclosure. The appearance of this term at various locations in the specification does not necessarily refer to the same embodiment, nor does it indicate that the embodiments are mutually exclusive or independent alternatives. Those skilled in the art will understand that the embodiments described herein may be combined with other embodiments.

The present disclosure will be described in detail with reference to the accompanying drawings and embodiments.

Referring to FIG. 1, FIG. 1 is a flowchart of a manufacturing method of a display panel according to Implementation 1 of the present disclosure. In the present embodiments, a flowchart illustrating a manufacturing method of a display panel is provided, which includes operations at blocks illustrated herein.

At block S1: providing a preformed plate 100.

At block S2: depositing and forming a light-emitting layer 40 and a cathode 44 on the preformed plate 100 in sequence.

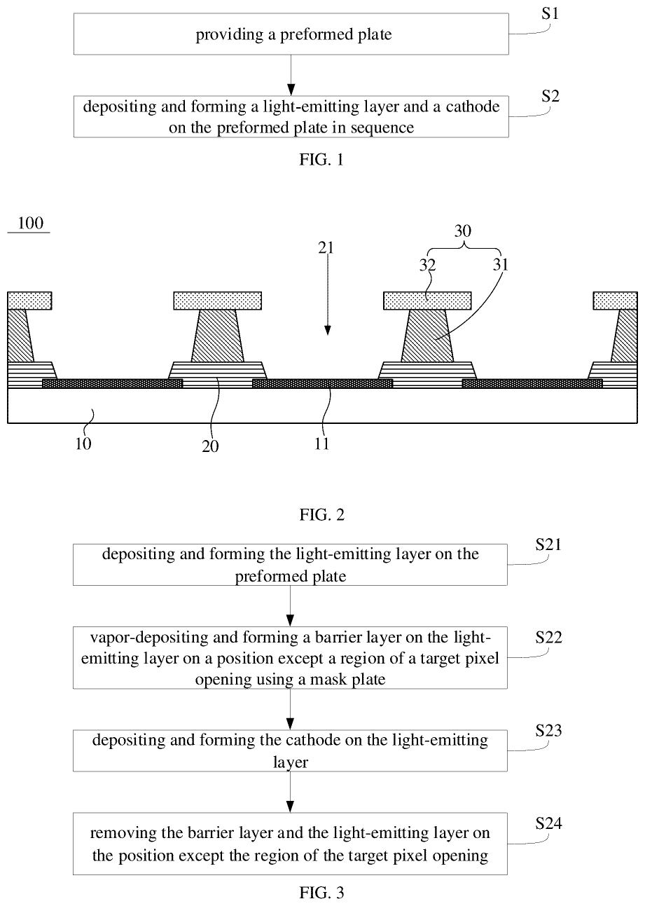

Referring to FIG. 2, FIG. 2 is a structural schematic view of a preformed plate according to some embodiments of the present disclosure. Specifically, in S1, the preformed plate 100 includes a drive substrate 10, anodes 11, a pixel definition layer 20, and conductive isolation structures 30. The anodes 11 and the pixel definition layer 20 are disposed on the drive substrate 10, the pixel definition layer 20 defines multiple pixel openings 21, the anodes 11 are disposed within the pixel openings 21 in a one-to-one correspondence, and the conductive isolation structures 30 protrude from the pixel definition layer 20 and surrounds the pixel openings 21.

In S2, the light-emitting layer 40 and the cathode 44 are sequentially deposited on the preformed plate 100 to form subpixel units P for light emission. Specifically, in each pixel opening 21, the anode 11, the light-emitting layer 40, and the cathode 44 are sequentially stacked to constitute a corresponding subpixel unit P, and the cathode 44 is in contact with and electrically connected to corresponding conductive isolation structure(s) 30.

As shown in FIG. 2, the drive substrate 10 further includes a drive circuit (not shown), which is electrically connected to the anode 11 and is configured to drive the subpixel unit P to emit light. The drive substrate 10 may specifically be a rigid substrate or a flexible substrate, which may be selected based on application scenarios and usage requirements.

The pixel definition layer 20 protrudes from the drive substrate 10 to define the pixel openings 21 for accommodating the subpixel units P. The pixel openings 21 are arranged in an array, which may be specifically designed according to the arrangement of the subpixel units P. The pixel definition layer 20 may be patterned using a photolithography process or other patterning processes.

The conductive isolation structures 30 are configured to isolate each subpixel unit P. Specifically, the conductive isolation structures 30 separate portions of the light-emitting layer 40 corresponding to the subpixel units P and separates portions of the cathode 44 corresponding to subpixels of different colors to prevent pixel crosstalk. Additionally, the portions of cathode 44 corresponding to the subpixel units P are in contact with and electrically connected to the conductive isolation structures 30, to electrically connect the portions of cathode 44 corresponding to the subpixel units P through the conductive isolation structures 30, thereby achieving a mesh-like connection between different subpixel units P and ensuring uniformity of the signal across the entire cathode 44.

Specifically, each conductive isolation structure 30 includes a conductive structure 31 and a top structure 32 stacked in sequence. The conductive structure 31 is protruding on the pixel definition layer 20 and surrounds the pixel openings 21; the top structure 32 is disposed on an upper surface of the conductive structure 31, covering the conductive structure 31 and extending from the conductive structure 31 in a direction parallel to the pixel definition layer 20. That is, the top structure 32 is in contact with the conductive structure 31, and a positive projection of the top structure 32 on the drive substrate 10 completely covers a positive projection of the conductive structure 31 on the drive substrate 10. Specifically, a portion of the top structure 32 extending out of the conductive structure 31 is suspended relative to the conductive structure 31.

In S2, the light-emitting layer 40 and the cathode 44 may be sequentially deposited on the preformed plate 100 through a vapor-deposition method. The conductive isolation structure 30 on the preformed plate 100 may replace a mask plate for the vapor-deposition of the light-emitting layer 40 and the cathode 44. During the vapor-deposition of the light-emitting layer 40 and the cathode 44, the vapor-deposition angle may be adjusted by the suspended portion of the top structure 32, so as to regulate an edge range size of each film layer in the light-emitting layer 40. The conductive isolation structures 30 are multiple in number, with adjacent conductive isolation structures 30 sharing a same side edge to ensure equal spacing between subpixel units P, thereby enhancing display uniformity. Specifically, the conductive isolation structure 30 is a ring-shaped structure that matches the shape of the subpixel unit P, serving to prepare the subpixel unit P with a predetermined shape.

In a direction perpendicular to the drive substrate 10, a longitudinal cross-section of a side wall of the conductive structure 31 is trapezoidal, and traverse cross-sections of the side wall of the conductive structure 31 gradually decrease in size toward the top structure 32, thereby facilitating the contact and arrangement of the cathode 44 with the conductive structure 31.

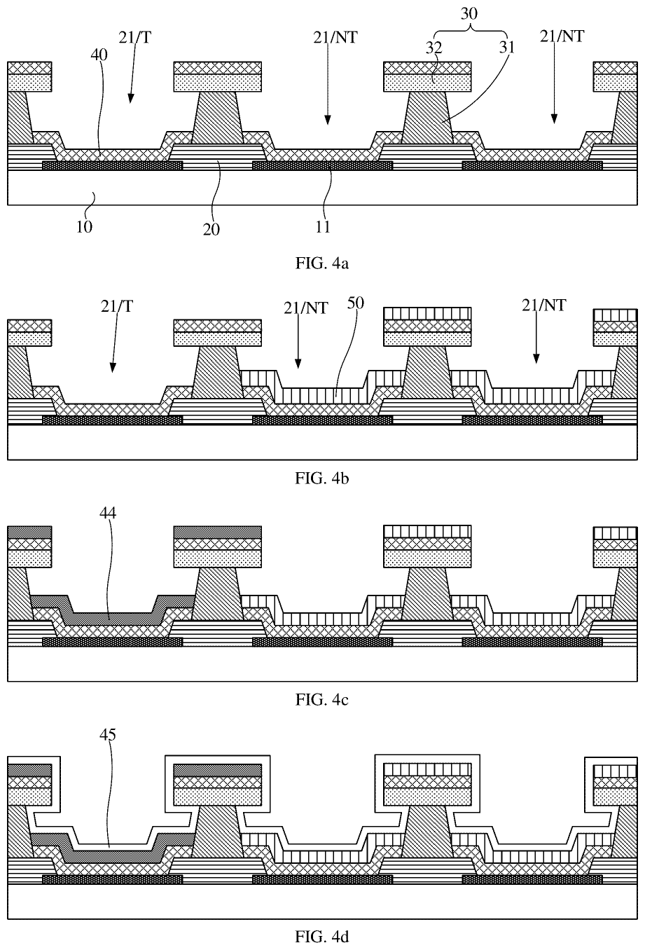

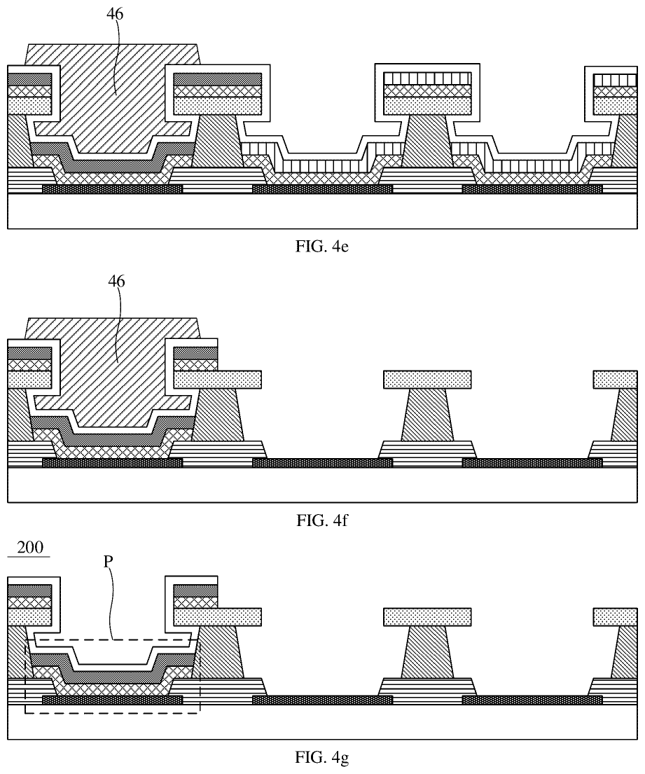

Referring to FIGS. 3, 4a to 4g, FIG. 3 is a flowchart of operation S10 in the manufacturing method as illustrated in FIG. 1 according to some embodiments of the present disclosure, and FIGS. 4a-4g are schematic diagrams of operations in the manufacturing method as illustrated in FIG. 3 according to some embodiments of the present disclosure. Specifically, the operation S2 includes operations at blocks illustrated in FIG. 3.

At block S21: depositing and forming the light-emitting layer 40 on the preformed plate 100.

At block S22: vapor-depositing and forming a barrier layer 50 on the light-emitting layer 40 on a position except a region of a target pixel opening T using a mask plate.

At block S23: depositing and forming the cathode 44 on the light-emitting layer 40.

At block S24: removing the barrier layer 50 and the light-emitting layer 40 on the position except the region of the target pixel opening T.

In the embodiments, S2 is performed for preparing subpixel light-emitting units, where the pixel openings 21 corresponding to the prepared subpixel units P are each taken as the target pixel opening T. For example, S2 is performed to prepare and form red subpixel units P, the pixel openings 21 for accommodating the red subpixel units P are taken as the target pixel openings T in this process, while the other pixel openings 21 serve as non-target pixel openings NT.

In S21, the conductive isolation structures 30 are used to deposit and form the light-emitting layer 40 by vapor-deposition, thereby depositing and forming the light-emitting layer 40 in the pixel openings 21. For example, a red subpixel unit P is required to be prepared in this process, material of a red light-emitting layer 40 is vapor-deposited to deposit and form the red light-emitting layer 40 in each pixel opening 21.

Then, in S22, a barrier layer 50 is prepared by vapor-deposition on the light-emitting layer 40 except the region of the target pixel opening T using a corresponding mask plate. Specifically, the corresponding mask plate is aligned with the preformed plate 100 such that the mask plate blocks the target pixel opening T in the direction perpendicular to the preformed plate 100, exposing the other pixel openings 21, and then the barrier layer material is vapor-deposited to deposit and form the barrier layer 50 on the light-emitting layer 40 except the region of the target pixel opening T. Specifically, the barrier layer 50 is mutually repulsive with the cathode material to prevent the cathode material from being deposited in the region of the non-target pixel openings NT, thereby preventing the cathode material from adhering to the barrier layer 50 and allowing it to deposit only on the light-emitting layer 40 within the target pixel opening T to form the corresponding cathode 44.

In S23, cathode material is vapor-deposited by means of the conductive isolation structures 30 to form the cathode 44 on the light-emitting layer 40. Specifically, since the barrier layer 50 is located on the light-emitting layer 40 except the region of the target pixel opening T, during the vapor-deposition of the cathode material, the cathode material can only be deposited on the light-emitting layer 40 within the target pixel opening T to form the cathode 44. Therefore, the cathode 44 cannot be formed in regions except the region of the target pixel opening T.

Subsequently, film layers deposited in the region of the non-target pixel openings NT must be removed, leaving only the anode 11 to support the preparation of other subpixel units P in subsequent processes. In S24, when removing the film layers deposited except the region of the target pixel opening T, there is no need to etch the cathode 44 again. Instead, only the barrier layer 50 and the light-emitting layer 40 except the region of the target pixel opening T are required to be etched in a single step, which eliminates a cathode etching process, thereby reducing process complexity, and avoiding local residue caused by the issue of incomplete cathode etching, and thus improving product brightness.

It should be noted that in the specific manufacturing process, during the process of removing the film layers except regions of the pixel openings 21, the cathode 44 is typically etched using a wet etching method, while the light-emitting layer 40 and other film layers, such as a protective layer 45, are typically etched using a dry etching method. Therefore, the process is relatively complex and typically requires three etching steps to remove the desired film layers.

To address the above technical issues, in the embodiments, prior to depositing and forming the cathode 44, a barrier layer 50 that is mutually repulsive with the cathode material is vapor-deposited and formed on the light-emitting layer 40 in the regions of the non-target pixel openings NT, i.e., the region to be etched, using a corresponding mask plate. This may prevent the cathode material from adhering to the region to be etched. thereby eliminating the need for an additional cathode etching process. The light-emitting layer 40, barrier layer 50, and other film layers that require etching are only required to undergo a single etching process, thereby reducing process complexity and avoiding local residue caused by the issue of incomplete cathode etching, and thus improving product brightness.

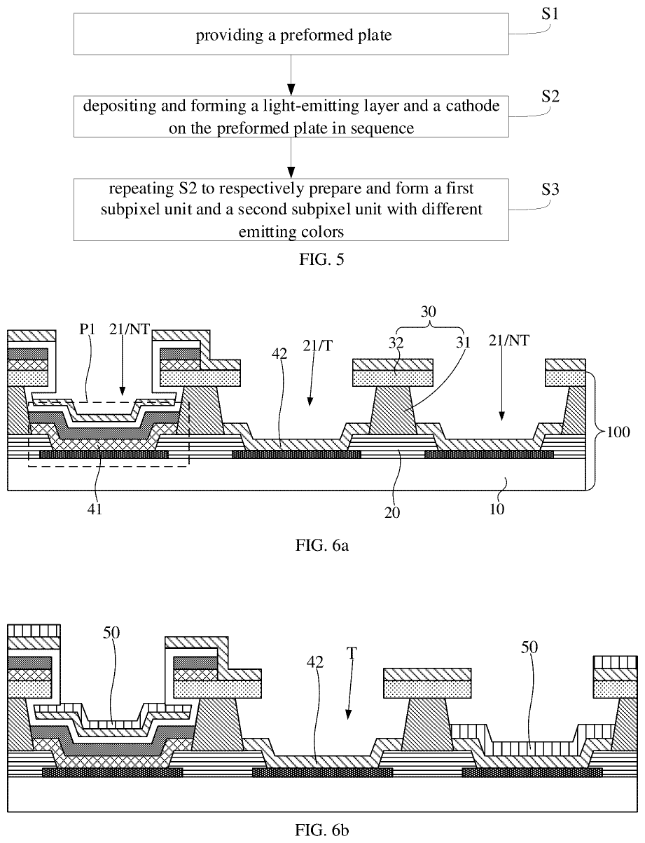

Referring to FIG. 5, FIG. 5 is a flowchart of a manufacturing method of a display panel according to Implementation 2 of the present disclosure. In the present embodiments, a flowchart illustrating a manufacturing method of a display panel 200 is provided, which includes operations at blocks illustrated herein.

At block S1: providing a preformed plate 100.

At block S2: depositing and forming a light-emitting layer 40 and a cathode 44 on the preformed plate 100 in sequence.

At block S3: repeating S2 to respectively prepare and form a first subpixel unit P1 and a second subpixel unit P2 with different emitting colors.

In the embodiments, S1 and S2 are the same as S1 and S2 described in the preceding embodiments, and the specific structure and function of the preformed plate 100 provided in S1 are the same as those of the preformed plate 100 provided in the embodiments of FIG. 2, and may achieve the same technical effect. For details, reference may be made to the preceding detailed description.

The specific process corresponding to S2 is shown in FIGS. 3 and 4a to 4g. In this operation, the first light-emitting layer 41 is deposited and formed through S21. In the embodiments, S2 is performed to form the first subpixel unit P1, and S3 is performed to form the second subpixel unit P2. The first subpixel unit P1 is configured to emit light of a first color, and the second subpixel unit P2 is configured to emit light of a second color.

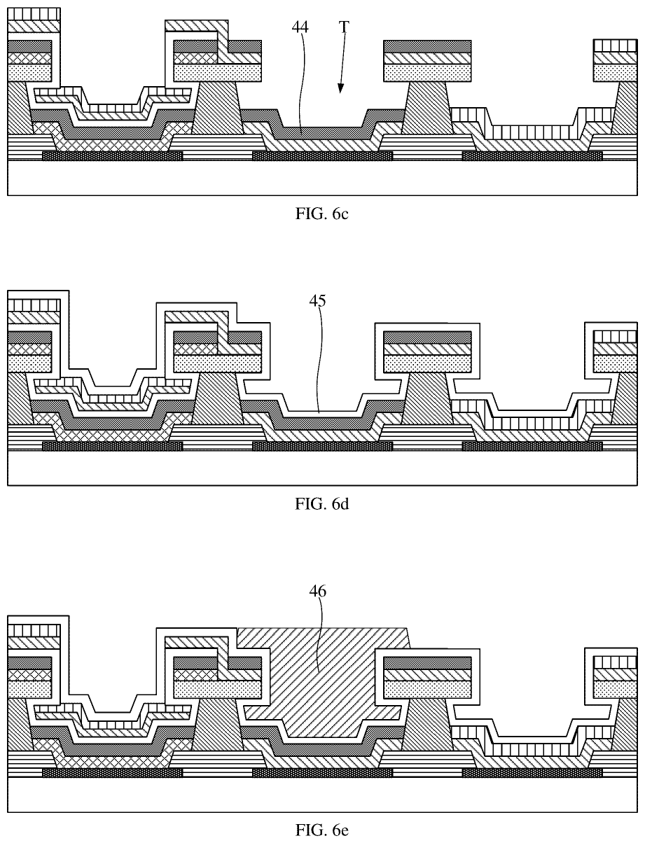

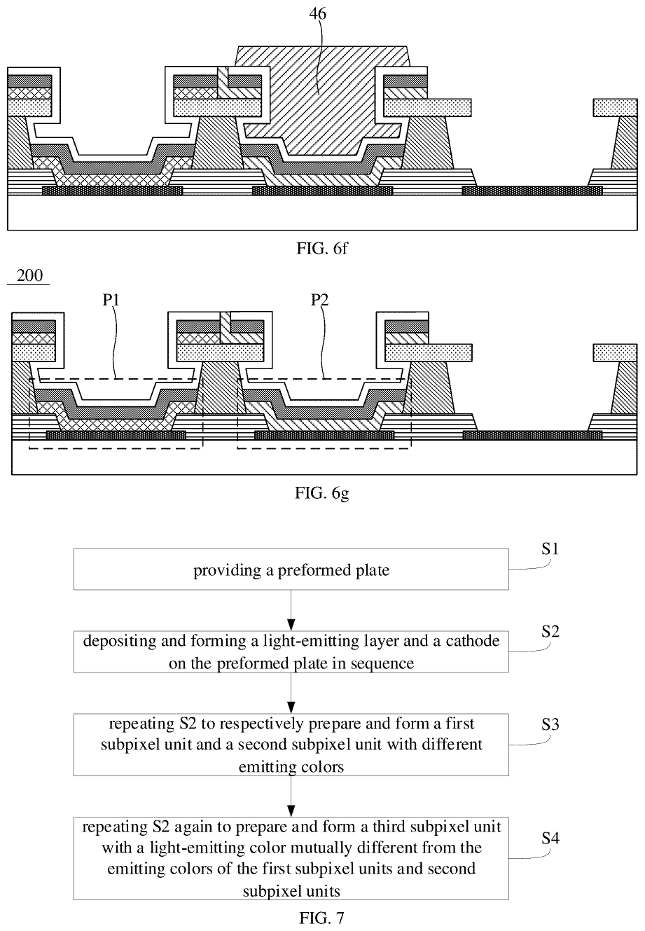

Specifically, referring to FIGS. 6a to 6g, FIGS. 6a-6g are schematic diagrams of operation S3 in the manufacturing method as illustrated in FIG. 5 according to some embodiments of the present disclosure. In S3, i.e., during the process of preparing the second subpixel unit P2, the process is essentially the same as that for preparing the first subpixel unit P1. In this process, the pixel opening 21 corresponding to the second subpixel unit P2 is designated as the target pixel opening T, while the other pixel openings 21 are designated as non-target pixel openings NT. It can be understood that, in the process of manufacturing different subpixel units P, the target pixel opening T is different, and the target pixel opening T varies with the subpixel unit P being prepared. That is, whichever subpixel unit P is being prepared, the pixel opening 21 to accommodate that subpixel unit P serves as the target pixel opening T, while the other pixel openings 21 all serve as non-target pixel openings NT.

During the process of preparing the second subpixel unit P2, first, material of a second light-emitting layer 42 is vapor-deposited using the conductive isolation structures 30 to form the second light-emitting layer 42 in each pixel opening 21. Then, using a corresponding second mask plate, a barrier layer 50 is deposited on the light-emitting layer 40 except the region of the target pixel opening T. Specifically, the corresponding second mask plate is aligned with the preformed plate 100 on which the first subpixel unit P1 has been fabricated, such that the second mask plate blocks the target pixel opening T in the direction perpendicular to the preformed plate 100, exposing the other pixel openings 21. Using the second mask plate, the barrier layer material is deposited to form the barrier layer 50 on the second light-emitting layer 42 except the region of the target pixel opening T. Specifically, the barrier layer 50 is mutually repulsive with the cathode material to prevent the cathode material from being deposited in the region except the region of the target pixel opening T, thereby preventing the cathode material from adhering to the barrier layer 50, and the cathode material can only be deposited on the light-emitting layer 40 within the target pixel opening T to form the corresponding cathode 44.

Then, using the conductive isolation structures 30 and the barrier layer 50, the cathode material is deposited to form the cathode 44 on the second light-emitting layer 42 within the target pixel opening T. In this operation, since the barrier layer 50 is disposed in the region except the region of the target pixel opening T, during the vapor-deposition of the cathode material, the cathode material can only be deposited on the second light-emitting layer 42 within the target pixel opening T to form the cathode 44. Therefore, the cathode 44 cannot be formed in the region except the region of the target pixel opening T.

When removing the film layers deposited except the region of the target pixel opening T, since the cathode 44 is not deposited in the region to be etched, there is no need to etch the cathode 44. Instead, only the barrier layer 50 and the second light-emitting layer 42 except the region of the target pixel opening T are required to be etched in a single step, thereby saving the cathode 44 etching process, reducing process complexity, and avoiding local residue caused by the issue of incomplete cathode etching, and thus improving product brightness.

Referring to FIG. 7, FIG. 7 is a flowchart of a manufacturing method of a display panel according to Implementation 3 of the present disclosure. In the present embodiments, a flowchart illustrating a manufacturing method of a display panel 200 is provided, which includes operations at blocks illustrated herein.

At block S1: providing a preformed plate 100.

At block S2: depositing and forming a light-emitting layer 40 and a cathode 44 on the preformed plate 100 in sequence.

At block S3: repeating S2 to respectively prepare and form a first subpixel unit P1 and a second subpixel unit P2 with different emitting colors.

At block S4: repeating S2 again to prepare and form a third subpixel unit P3 with a light-emitting color mutually different from the emitting colors of the first subpixel units P1 and second subpixel units P2.

In the embodiments, S1 to S3 are the same as S1 to S3 described in the preceding embodiments, and the specific structure and function of the preformed plate 100 provided in S1 are the same as those of the preformed plate 100 provided in the embodiments of FIG. 2, and may achieve the same technical effect. For details, reference may be made to the preceding detailed description.

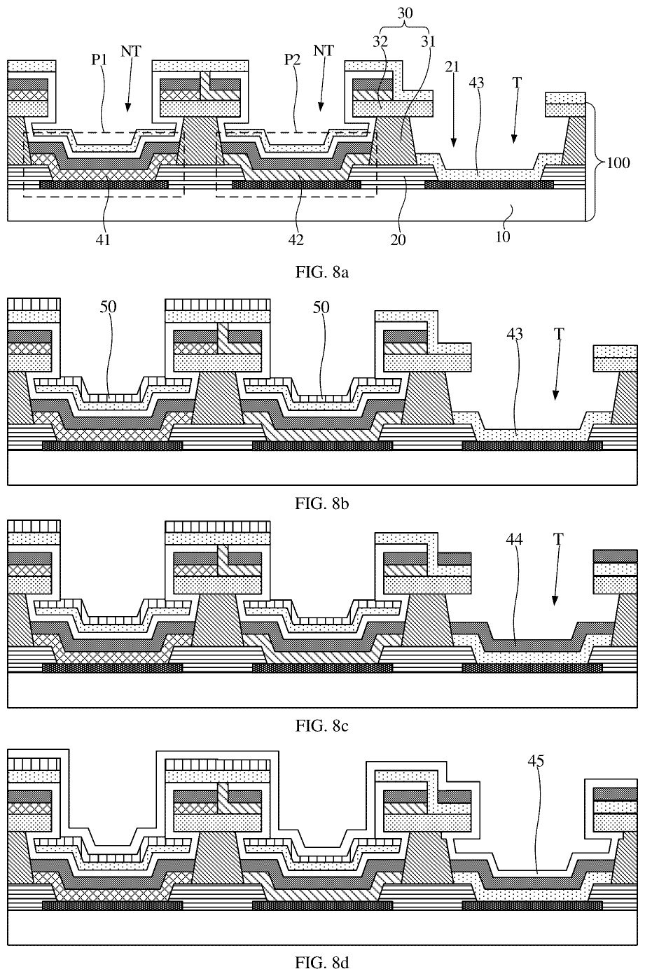

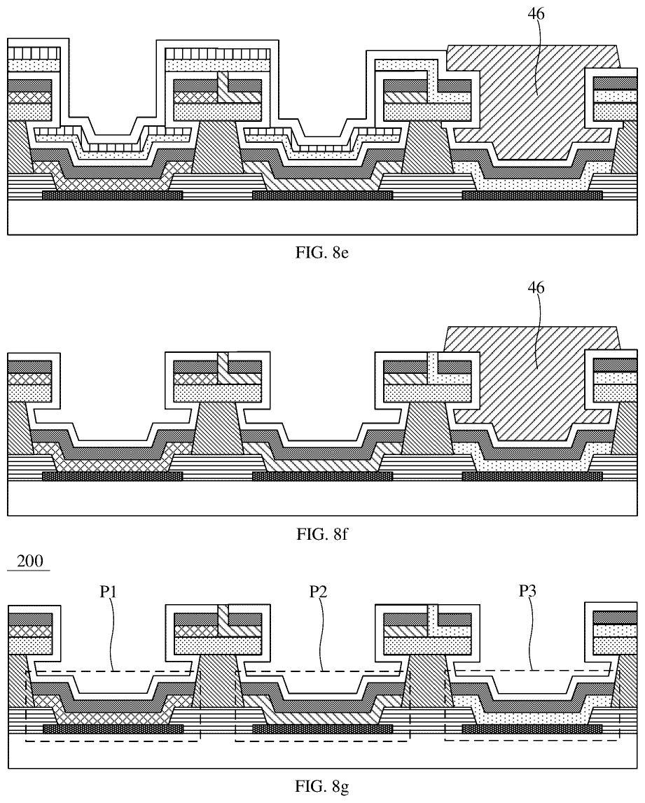

Referring to FIGS. 8a to 8g, FIGS. 8a-8g are schematic diagrams of operation S4 in the manufacturing method as illustrated in FIG. 7 according to some embodiments of the present disclosure. Similarly to the process for preparing the first subpixel unit P1 and the second subpixel unit P2, in S4, S2 is repeated to prepare the third subpixel unit P3. Similarly, S4 is performed to prepare the third subpixel unit P3. In this process, the pixel opening 21 corresponding to the third subpixel unit P3 is taken as the target pixel opening T, while the other pixel openings 21 serve as non-target pixel openings NT. In this process, the third mask plate is aligned with the preformed plate 100 using a corresponding third mask plate, such that the third mask plate blocks the target pixel opening T in the direction perpendicular to the preformed plate 100, exposing the other pixel openings 21. Using the third mask plate, the barrier layer material is deposited to form the barrier layer 50 on the third light-emitting layer 43 except the region of the target pixel opening T. This ensures that during the subsequent deposition of the cathode material, the cathode 44 can only be deposited on the third light-emitting layer 43 within the target pixel opening T. When removing the film layers deposited except the region of the target pixel opening T, there is no need to etch the cathode 44, and only the barrier layer 50 and the third light-emitting layer 43 except the region of the target pixel opening T are required to be etched in a single step, which eliminates a cathode etching process, thereby reducing process complexity, and avoiding local residue caused by the issue of incomplete cathode etching, and thus improving product brightness.

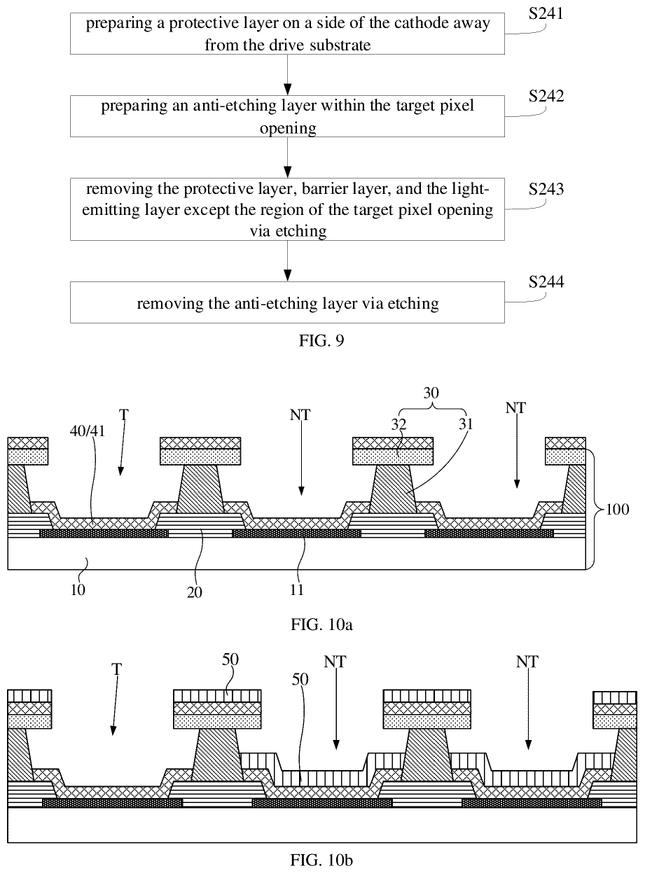

Referring to FIG. 9, FIG. 9 is a flowchart of operation S24 according to some embodiments of the present disclosure. Specifically, in the above embodiments, regarding the removal of the barrier layer 50 and the light-emitting layer 40 except the region of the target pixel opening T in S24, the following operations at blocks illustrated herein are included.

At block S241: preparing a protective layer 45 on a side of the cathode 44 away from the drive substrate 10.

At block S242: preparing an anti-etching layer 46 within the target pixel opening T.

At block S243: removing the protective layer 45, barrier layer 50, and the light-emitting layer 40 except the region of the target pixel opening T via etching.

At block S244: removing the anti-etching layer 46 via etching.

Specifically, referring to FIGS. 4d to 4g, 6d to 6g, and 8d to 8g, before etching the barrier layer 50 and the light-emitting layer 40, a protective layer 45 is prepared on a side of the cathode 44 away from the drive substrate 10 to protect the first subpixel unit P1, second subpixel unit P2, or third subpixel unit P3 formed in this process, preventing damage to the subpixel units P1, P2, or P3 during subsequent etching steps. An anti-etching layer 46 is then prepared within the target pixel opening T, i.e., the anti-etching layer 46 is filled and formed within the target pixel opening T, such that the anti-etching layer 46 fills the recessed region of the target pixel opening T and covers the exposed surfaces of the protective layers 45 of the conductive isolation structures 30 on both sides.

Then, in S243, the protective layer 45 except the region of the target pixel opening T is removed using an appropriate etching method to expose the anode 11 within the non-target pixel opening NT, facilitating the subsequent formation of other subpixel units P. Specifically, in the embodiments, the etching method may employ wet etching or dry etching processes, with the specific choice determined based on particular manufacturing requirements.

In the embodiments of the present disclosure, the material of the barrier layer 50 may specifically include cathode patterning material (CPM). In some embodiments, the CPM material is a fluorine-containing organic material, such as a fluorine-substituted tricyclopropane compound. The CPM material may be deposited on the drive substrate 10 via low-temperature vacuum vapor-deposition to form the barrier layer 50. In other embodiments, the CPM material may not be a fluorine-containing organic material, provided that the CPM material is incompatible with metal materials and mutually repels them. The cathode material may specifically include metal materials. The film layer formed by the CPM material repels the metal material, thereby utilizing this property of the CPM material to form the barrier layer 50. This barrier layer may prevent the cathode material from being deposited on region of the non-target pixel openings NT, thereby ensuring that the cathode 44 can only be deposited and formed on the light-emitting layer 40 within the target pixel opening T.

Specifically, the cathode material may include magnesium (Mg), silver (Ag), aluminum (Al), lithium (Li), calcium (Ca), indium (In), or magnesium-silver alloy (Mg:Ag), lithium-aluminum alloy (Li:Al). The specific material may be selected based on actual preparation requirements. The anode material 11 may be the same as the cathode material, or the anode material 11 may include metal oxides, such as indium tin oxide (ITO), indium zinc oxide (IZO), or indium gallium zinc oxide (IGZO); or the anode 11 may be a layered structure of different materials.

Specifically, the display panel 200 prepared using the manufacturing method provided in the above embodiments may be a top-emitting mode or a bottom-emitting mode. In the top-emitting mode display panel 200, light emitted from the light-emitting layer 40 in the subpixel unit P is emitted through the cathode 44, and the thickness of the cathode 44 in the direction perpendicular to the drive substrate 10 is in a range from 5 nm to 50 nm, such as 10 nm, 15 nm, 20 nm, or 30 nm, which may be specifically set according to actual requirements. The thickness of the anode 11 is not less than 100 nm in the direction perpendicular to the drive substrate 10 to enhance the reflective effect of the anode 11, thereby improving the light utilization efficiency of the display panel 200. In the bottom-emitting mode of the display panel 200, the light emitted from the light-emitting layer 40 in the subpixel unit P is emitted through the anode 11. The thickness of the anode 11 in the direction perpendicular to the drive substrate 10 is in a range from 5 nm to 50 nm, such as 10 nm, 15 nm, 20 nm, or 30 nm; the thickness of the cathode 44 in the direction perpendicular to the drive substrate 10 is not less than 100 nm, to enhance the reflective effect of the cathode 44, thereby improving the light utilization efficiency of the display panel 200.

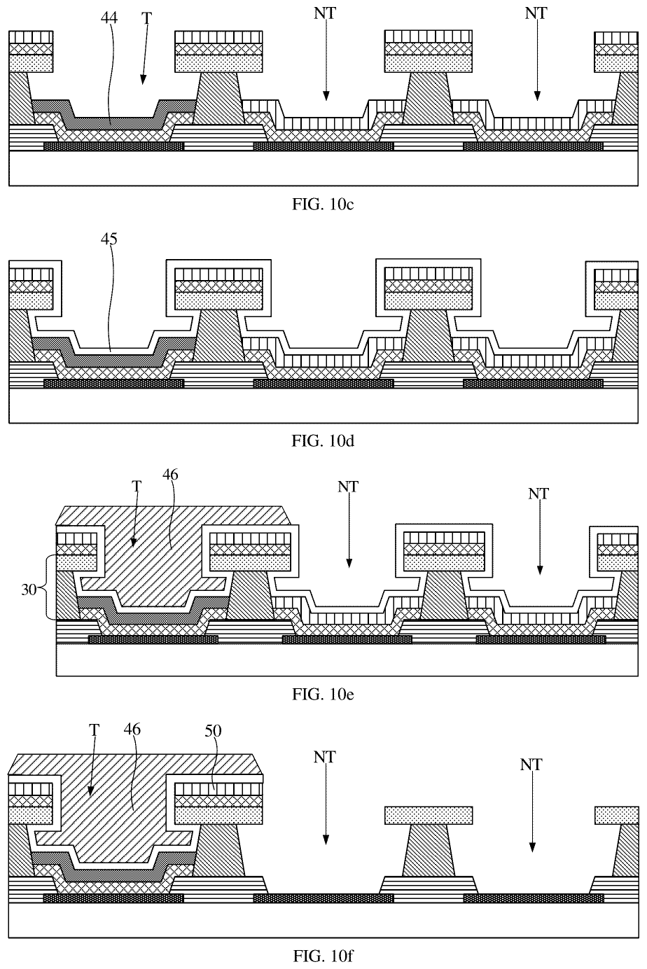

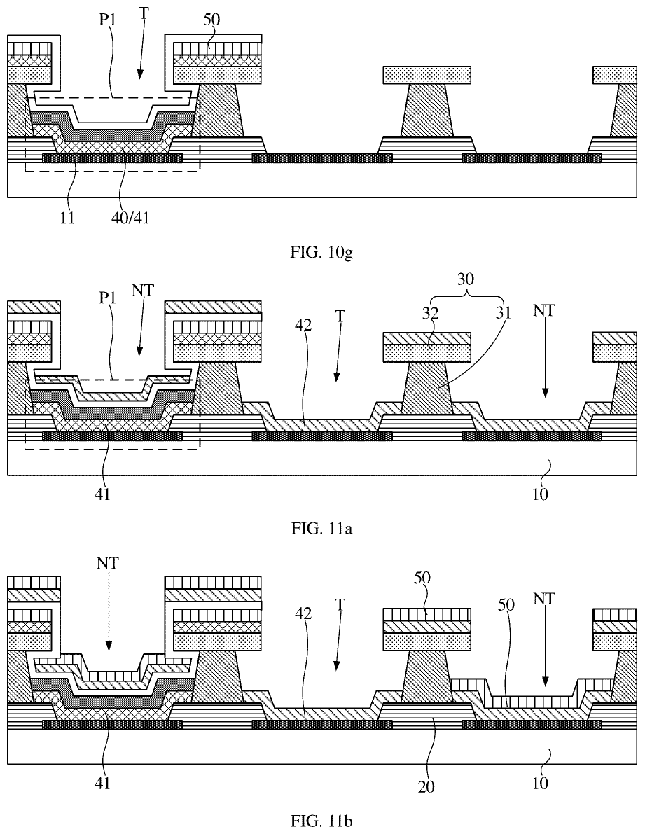

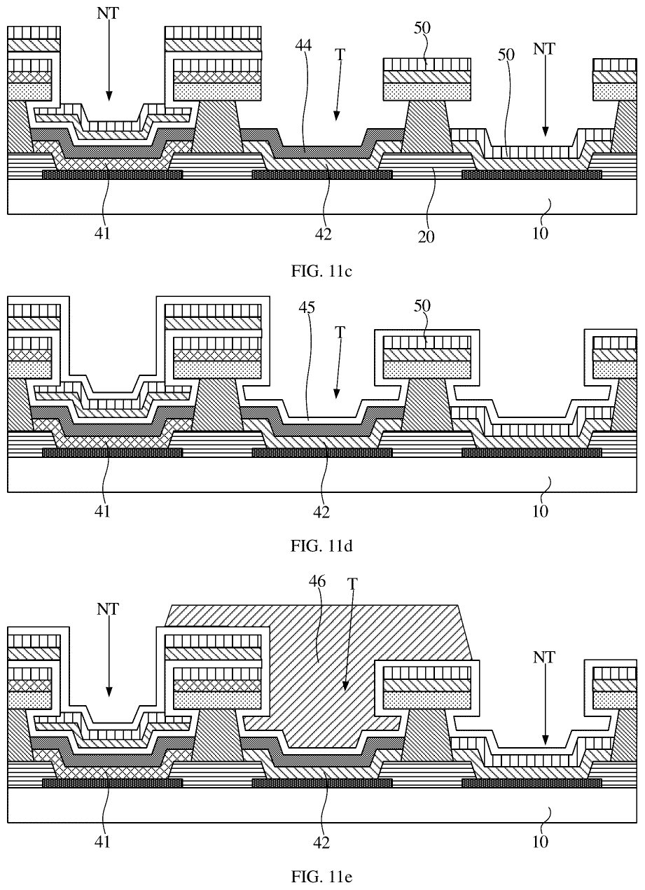

Referring to FIGS. 10a-10g, FIGS. 10a-10g are schematic diagrams of a manufacturing process of a first subpixel unit in the manufacturing method as illustrated in FIG. 7 according to some embodiments of the present disclosure. In the embodiments, regarding the S22 of depositing and forming a barrier layer 50 on the light-emitting layer 40 on a position except a region of a target pixel opening T using a mask plate, the barrier layer 50 is formed in the non-target pixel openings NT and on a side of each conductive isolation structure 30 away from the drive substrate 10.

As shown in FIG. 10b, in S22, by using the corresponding mask plate to block the target pixel opening T, during the vapor-deposition process, the barrier layer material is deposited on the preformed plate 1000 on the position except the region of the target pixel opening T, including the non-target pixel openings NT and the conductive isolation structure 30, thereby forming the barrier layer 50 in the non-target pixel openings NT and on the conductive isolation structures 30.

As shown in FIG. 10c, due to the mutual repulsion between the barrier layer 50 and the cathode material, during the cathode material vapor-deposition process, the cathode material is deposited only within the target pixel opening T and cannot be deposited on the conductive isolation structures 30 or within the non-target pixel openings NT.

Through the above manufacturing method, the cathode 44 is absent on the side of the conductive isolation structure 30 away from the drive substrate 10. Therefore, during subsequent etching to remove the barrier layer 50 and the light-emitting layer 40 except the region of the target pixel opening T, it is possible to avoid display abnormalities caused by issues where particles of cathode 44 remaining at the edges of the top structure 32 of the conductive isolation structure 30 fall into adjacent pixel openings 21 during etching.

Specifically, in the embodiments, the subpixel units P include first, second, and third subpixel units P1, P2, and P3 with different light-emitting colors, which may be red, green, and blue, respectively. The first subpixel unit P1 may be formed through the process shown in FIGS. 10a to 10g.

Furthermore, as shown in FIGS. 10d to 10g, in the present embodiments, S24 of removing the barrier layer 50 and the light-emitting layer 40 on the position except the region of the target pixel opening T may have similar specific operations to those in FIG. 9. The difference is that in S242 of preparing an anti-etching layer 46 within the target pixel opening T, the anti-etching layer 46 covers the target pixel opening T and the conductive isolation structures 30 surrounding the target pixel opening T.

It can be understood that by covering the target pixel opening T and the conductive isolation structures 30 surrounding the target pixel opening T with the anti-etching layer 46, during the process of etching the protective layer 45, barrier layer 50, and light-emitting layer 40 except the region of the target pixel opening T in S243, the barrier layer 50 on the conductive isolation structures 30 surrounding the target pixel opening T is not etched away and remains intact.

Referring to FIGS. 11a-11g, FIGS. 11a-11g are schematic diagrams of a manufacturing process of a second subpixel unit in the manufacturing method as illustrated in FIG. 7 according to some embodiments of the present disclosure. Similarly, when the pixel opening 21 corresponding to the second subpixel unit P2 is taken as the target pixel opening T, the above operations S21-S24 are repeated to form the second subpixel unit P2.

As shown in FIG. 11b, in S22, the target pixel opening T is masked using a corresponding mask plate, such that during the vapor-deposition process, the barrier layer material is deposited on the preformed plate 100 except the region of the target pixel opening T, including the non-target pixel openings NT and the regions of the conductive isolation structures 30, thereby forming the barrier layer 50 in the non-target pixel openings NT and on the conductive isolation structures 30. In this way, in S23, as shown in FIG. 11c, the cathode 44 is deposited only within the target pixel opening T, thereby avoiding the deposition of cathode 44 on the conductive isolation structures 30, and thus avoiding display abnormalities caused by the residual cathode particles falling into adjacent pixel openings 21 during subsequent etching processes.

Furthermore, as shown in FIG. 11e, during the process of manufacturing the second subpixel unit P2, in S242, the anti-etching layer 46 covers the target pixel opening T and the conductive isolation structures 30 surrounding the target pixel opening T, such that during S243 of removing the protective layer 45, barrier layer 50, and the light-emitting layer 40 except the region of the target pixel opening T via etching, the barrier layer 50 on the conductive isolation structures 30 surrounding the target pixel opening T is not etched away and remains intact.

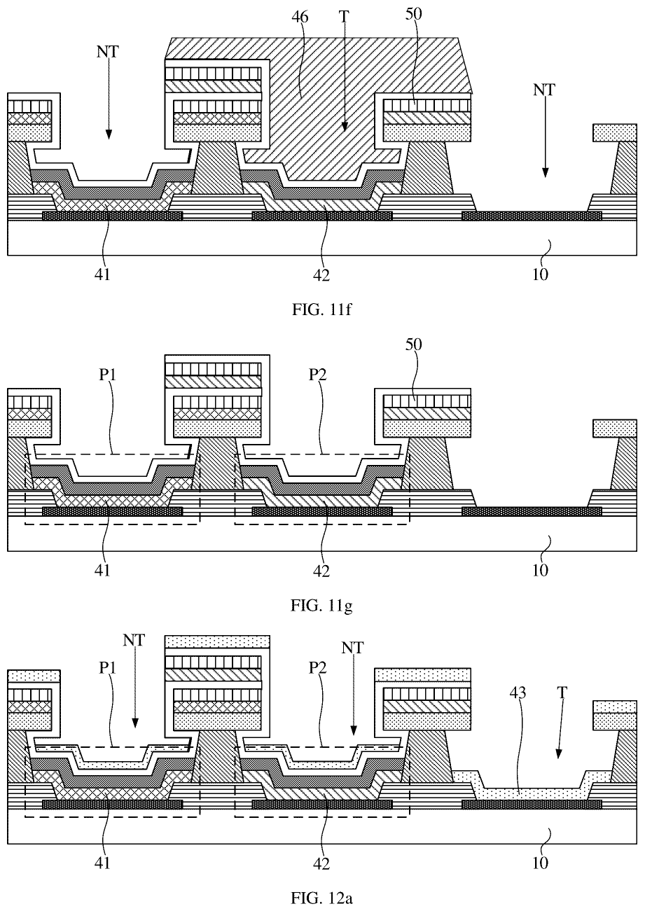

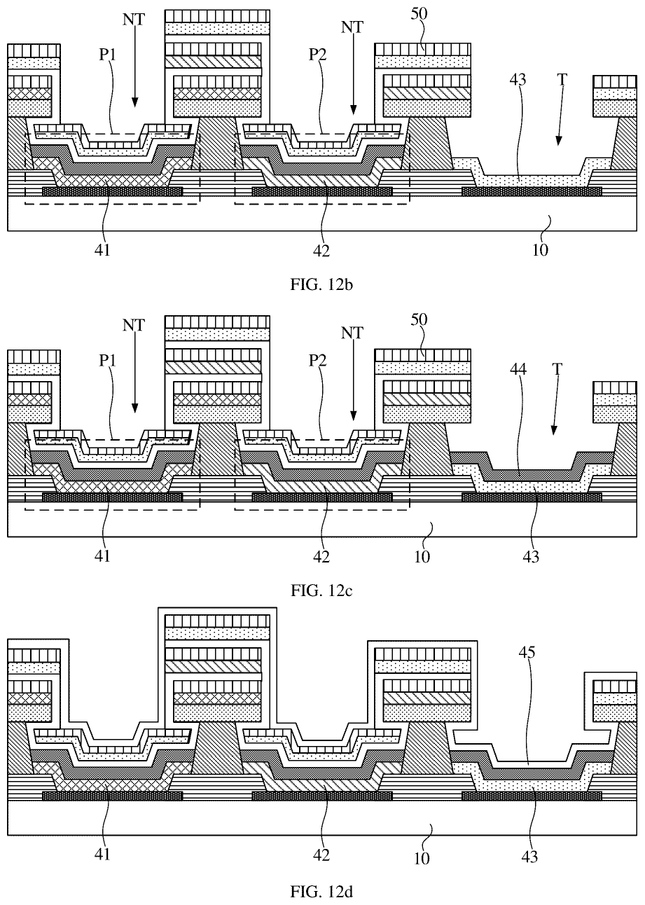

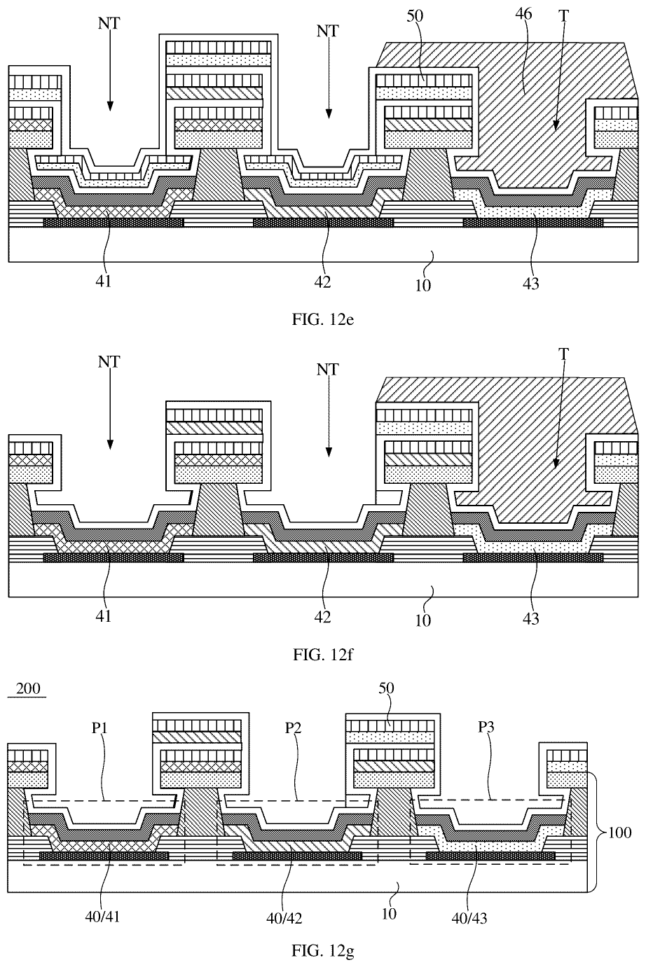

Referring to FIGS. 12a-12g, FIGS. 12a-12g are schematic diagrams of a manufacturing process of a third subpixel unit in the manufacturing method as illustrated in FIG. 7 according to some embodiments of the present disclosure. In this process, the third subpixel unit P3 is fabricated. Therefore, the pixel opening 21 corresponding to the third subpixel unit P3 is taken as the target pixel opening T, and the above operations S21-S24 are repeated to form the third subpixel unit P3.

As shown in FIG. 12b, in S22, the barrier layer material is deposited on the preformed plate 100 except the region of the target pixel opening T, i.e., the barrier layer material is deposited on the third light-emitting layer 43 within the non-image pixel openings NT and on the top structure 32 of the conductive isolation structure 30. Thus, in the subsequent step of preparing the cathode 44, as shown in FIG. 12c, the cathode 44 is deposited only on the third light-emitting layer 43 within the target pixel opening T. As a result, during the subsequent etching process, there is no need to etch the cathode, thereby reducing the number of etching steps.

It should be noted that if the cathode material is deposited except the region of the target pixel opening T, it must be etched. Since the cathode material is different from the material of the protective layer 45 and the light-emitting layer 40, the etching process requires three etching steps: wet etching, dry etching, and wet etching. In the embodiments of the present disclosure, the cathode material is deposited only within the target pixel opening T and does not require etching, and thus only one etching step is needed, thereby effectively simplifying the etching process steps. Additionally, the above design may avoid the issue of cathode particles falling into adjacent pixel openings 21 during cathode etching.

As shown in FIGS. 12e-12g, during the etching process, the anti-etching layer 46 is caused to cover the target pixel opening T and the conductive isolation structures 30 surrounding the target pixel opening T. As a result, after etching, the barrier layer 50 on the conductive isolation structures 30 surrounding the target pixel opening T is retained.

Therefore, in the process of preparing each of the first subpixel unit P1, the second subpixel unit P2, and the third subpixel unit P3, the anti-etching layer 46 is arranged covering the target pixel opening T and the conductive isolation structures 30 surrounding the target pixel opening T, such that the barrier layer 50 on the conductive isolation structures 30 surrounding the target pixel opening T is covered, thereby preventing the barrier layer 50 on the conductive isolation structures 30 surrounding the target pixel opening T from being etched away during the etching process. As a result, in the process of forming each subpixel unit P, the barrier layer 50 on the conductive isolation structures 30 surrounding the target pixel opening T is retained. That is, in S24 of removing the barrier layer 50 and the light-emitting layer 40 on the position except the region of the target pixel opening T, a portion of the barrier layer 50 located on the conductive isolation structures 30 is retained to further prevent the cathode 44 from being deposited on the conductive isolation structure 30, thereby avoiding affecting the etching of the light-emitting layer 40 during the etching process and preventing cathode particles from falling into adjacent pixel openings 21 at the side edges of the conductive isolation structure 30, which could cause display abnormalities.

In some embodiments of the present disclosure, a display panel 200 is provided, which may be manufactured using the manufacturing method described above. The specific structure of the display panel 200 is shown in FIG. 8g or 12g. The display panel 200 includes a drive substrate 10, a pixel definition layer 20, conductive isolation structures 30, and subpixel units P.

Specifically, the specific structure and functions of the drive substrate 10, pixel definition layer 20, conductive isolation structures 30, and subpixel units P are the same as those of the drive substrate 10, pixel definition layer 20, conductive isolation structures 30, and subpixel units P described in the above embodiments, and may achieve the same technical effects.

A barrier layer 50 is arranged on the conductive isolation structure 30 on a side away from the drive substrate 10. The barrier layer 50 is mutually repulsive with the cathode material, preventing the cathode material from being deposited on the surface of the conductive isolation structure 30 away from the drive substrate 10, which may ensure that during the manufacturing process of the subpixel unit P, the cathode 44 is deposited only within the pixel opening 21, eliminating the need for additional etching of the cathode 44, thereby simplifying the manufacturing process. This may further prevent cathode material deposited on the conductive isolation structure 30 from affecting the etching of the light-emitting layer 40 during the etching step, and avoid cathode particles from the upper edge of the conductive isolation structure 30 falling into adjacent pixel openings 21, which could cause display abnormalities.

In the embodiments, the cathode 44 is fabricated using the conductive isolation structure 30 and the barrier layer 50, which not only improves the pixel opening rate and pixel density, simplifies the process, but also avoids the problem of local residue caused by incomplete etching of the cathode 44 during the manufacturing process, thereby improving the product yield of the display panel 200.

Furthermore, in the display panel 200, after preparing the corresponding subpixel unit P, a portion of the barrier layer 50 corresponding to the pixel opening 21 is removed, while retaining the portion of the barrier layer 50 located on a side of the conductive isolation structure 30 away from the drive substrate 10. That is, the side of the conductive isolation structure 30 away from the drive substrate 10 retains a portion of the barrier layer 50. The barrier layer 50 is made of CPM material, making it transparent with high transmittance. By retaining a portion of the barrier layer 50 on the side of the conductive isolation structure 30 away from the drive substrate 10, the transmittance of the display panel 200 may be improved.

Furthermore, to further improve the transmittance of the display panel 200, a light-emitting layer (CPL layer, not shown) may be arranged between the cathode 44 and the protective layer 45 in the subpixel unit P of the display panel 200, for reducing light loss caused by reflection from nearby electrodes during light emission, thereby improving the light efficiency of the display panel 200, i.e., increasing the refractive index of the light generated by the display panel 200, and improving the optical properties of the display panel 200 by suppressing light absorption.

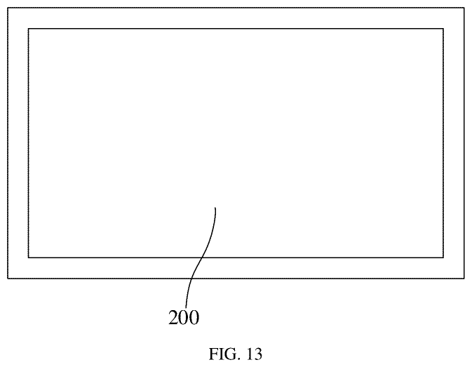

Referring to FIG. 13, FIG. 13 is a structural schematic view of a display device according to some embodiments of the present disclosure. In the present embodiments, a display device is provided that may be applied in fields such as flat panels, mobile phones, automotive, and lighting.

The display device includes a circuit board (not shown) and a display panel 200, with the circuit board electrically coupled to the display panel 200 to provide various drive signals, power signals, and other display signals required by the display panel 200. The specific structure and functions of the display panel 200 are the same or similar to those of the display panel 200 described in the preceding embodiments, and may achieve the same technical effects. For details, reference may be made to the preceding description. Specifically, the display panel 200 may be prepared using the manufacturing method provided in the preceding embodiments. The display device may effectively simplify the etching process, avoid local residue caused by incomplete cathode etching, and improve product yield.

The above is merely some embodiments of the present disclosure and does not limit the scope of the present disclosure. Any equivalent structures or equivalent process changes made based on the content of the specification and drawings of the present disclosure, or any direct or indirect application in other related technical fields, are similarly included within the scope of the present disclosure.

1. A manufacturing method of a display panel, comprising:
providing a preformed plate; wherein the preformed plate comprises a drive substrate, anodes, a pixel definition layer, and conductive isolation structures; the anodes and the pixel definition layer are disposed on the drive substrate, the pixel definition layer defines a plurality of pixel openings, and the anodes are disposed within the plurality of pixel openings in a one-to-one correspondence; the conductive isolation structures protrude from the pixel definition layer and surrounds the plurality of pixel openings; and
depositing and forming a light-emitting layer and a cathode on the preformed plate in sequence; wherein in each pixel opening, a corresponding anode, the light-emitting layer, and the cathode are sequentially stacked to constitute a corresponding subpixel unit, and the cathode is in contact with and electrically connected to at least corresponding one of the conductive isolation structures;
wherein the depositing and forming a light-emitting layer and a cathode on the preformed plate in sequence comprises in sequence:
depositing and forming the light-emitting layer on the preformed plate;
vapor-depositing and forming a barrier layer on the light-emitting layer on a position except a region of a target pixel opening by means of a mask plate; wherein the barrier layer is mutually repulsive with a material of the cathode to prevent the material of the cathode from being deposited in a region of a non-target pixel opening; wherein one of the plurality of pixel openings is defined as the target pixel opening, and remaining of the plurality of pixel openings is defined as the non-target pixel opening;
depositing and forming the cathode on the light-emitting layer; and
removing the light-emitting layer on the position except the region of the target pixel opening, and removing the barrier layer on at least a part of the position except the region of the target pixel opening.

2. The manufacturing method according to claim 1, wherein the depositing and forming a light-emitting layer and a cathode on the preformed plate in sequence is to prepare and form a first subpixel unit, and the method further comprises:
repeating the depositing and forming a light-emitting layer and a cathode on the preformed plate in sequence to prepare and form a second subpixel unit; wherein the first subpixel unit and the second subpixel unit are with different emitting colors;
wherein during the depositing and forming the light-emitting layer and the cathode on the preformed plate in sequence to prepare and form the first subpixel unit, one of the plurality of pixel openings corresponding to the first subpixel unit is defined as the target pixel opening; during the depositing and forming the light-emitting layer and the cathode on the preformed plate in sequence to prepare and form the second subpixel unit, one of the plurality of pixel openings corresponding to the second subpixel unit is defined as the target pixel opening.

3. The manufacturing method according to claim 2, wherein during the depositing and forming the light-emitting layer and the cathode on the preformed plate in sequence to prepare and form the first subpixel unit, the mask plate is defined as a first mask plate, and during the depositing and forming the light-emitting layer and the cathode on the preformed plate in sequence to prepare and form the second subpixel unit, the mask plate is defined as a second mask plate;
regarding the first subpixel unit, the vapor-depositing and forming a barrier layer on the light-emitting layer on a position except a region of a target pixel opening by means of a mask plate comprises:
aligning the first mask plate with the preformed plate, for causing the first mask plate to block the target pixel opening in a direction perpendicular to the preformed plate and to expose the remaining of the plurality of pixel openings; and
vapor-depositing material of the barrier layer to form the barrier layer on the light-emitting layer on the position except the region of the target pixel opening, for causing the cathode to be formed only on the light-emitting layer within the target pixel opening;
regarding the second subpixel unit, the vapor-depositing and forming a barrier layer on the light-emitting layer on a position except a region of a target pixel opening by means of a mask plate comprises:
aligning the second mask plate with the preformed plate, for causing the second mask plate to block the target pixel opening in a direction perpendicular to the preformed plate and to expose the remaining of the plurality of pixel openings; and
vapor-depositing material of the barrier layer to form the barrier layer on the light-emitting layer on the position except the region of the target pixel opening, for causing the cathode to be formed only on the light-emitting layer within the target pixel opening.

4. The manufacturing method according to claim 1, wherein the removing the light-emitting layer on the position except the region of the target pixel opening, and removing the barrier layer on at least a part of the position except the region of the target pixel opening comprise:
preparing a protective layer on a side of the cathode from the drive substrate;
preparing an anti-etching layer within the target pixel opening;
removing the protective layer, the barrier layer, and the light-emitting layer on the position except the region of the target pixel opening via etching; and
removing the anti-etching layer via etching.

5. The manufacturing method according to claim 1, wherein in the vapor-depositing and forming a barrier layer on the light-emitting layer on a position except a region of a target pixel opening by means of a mask plate, the barrier layer is formed within the non-target pixel opening and on a side of the conductive isolation structures away from the drive substate.

6. The manufacturing method according to claim 5, wherein in the removing the light-emitting layer on the position except the region of the target pixel opening, and removing the barrier layer on at least a part of the position except the region of the target pixel opening, the barrier layer on the side of the conductive isolation structures away from the drive substate is retained.

7. The manufacturing method according to claim 6, wherein the removing the light-emitting layer on the position except the region of the target pixel opening, and removing the barrier layer on at least a part of the position except the region of the target pixel opening comprise:
preparing a protective layer on a side of the cathode from the drive substrate; wherein the protective layer covers the plurality of pixel openings and the conductive isolation structures;
preparing an anti-etching layer within the target pixel opening; wherein the anti-etching layer covers the target pixel opening and the conductive isolation structures surrounding the target pixel opening;
removing the protective layer, the barrier layer, and the light-emitting layer on the position except the region of the target pixel opening via etching; and
removing the anti-etching layer via etching.

8. The manufacturing method according to claim 1, wherein a material of the barrier layer comprises cathode patterning material (CPM), and the material of the cathode comprises metal.

9. The manufacturing method according to claim 1, wherein each conductive isolation structure comprises a conductive structure and a top structure stacked in sequence; the conductive structure protrudes from the pixel definition layer and surrounds the plurality of pixel openings; the top structure is disposed on an upper surface of the conductive structure, covering the conductive structure and extending from the conductive structure in a direction parallel to the pixel definition layer.

10. The manufacturing method according to claim 9, wherein in a direction perpendicular to the drive substrate, a longitudinal cross-section of a side wall of the conductive structure is trapezoidal, and traverse cross-sections of the side wall of the conductive structure gradually decrease in size toward the top structure.

11. The manufacturing method according to claim 2, wherein the method further comprises:
repeating the depositing and forming a light-emitting layer and a cathode on the preformed plate in sequence again to prepare and form a third subpixel unit; wherein the first subpixel unit, the second subpixel unit, and the third subpixel unit are with different emitting colors.

12. The manufacturing method according to claim 1, wherein the display panel is in a top-emitting mode, a thickness of the cathode in a direction perpendicular to the drive substrate is in a range from 5 nm to 50 nm, and a thickness of each anode is not less than 100 nm in the direction perpendicular to the drive substrate; or
the display panel is in a bottom-emitting mode, a thickness of each anode in a direction perpendicular to the drive substrate is in a range from 5 nm to 50 nm, and a thickness of the cathode in the direction perpendicular to the drive substrate is not less than 100 nm.

13. A display panel, comprising:
a drive substrate;
a pixel definition layer, disposed on the drive substrate and defining a plurality of pixel openings;
conductive isolation structures, protruding from the pixel definition layer and surrounding the plurality of pixel openings; and
subpixel units, comprising: anodes, a light-emitting layer, and a cathode stacked in sequence disposed in the plurality of pixel openings; wherein the cathode is in contact with and electrically connected to the conductive isolation structures;
wherein the subpixel units comprise a first subpixel unit and a second subpixel unit that are with different emitting colors;
a barrier layer is arranged on a side of the conductive isolation structures away from the drive substate; the barrier layer is mutually repulsive with a material of the cathode to prevent the material of the cathode from being deposited on the side of the conductive isolation structures away from the drive substate.

14. The display panel according to claim 1, wherein each conductive isolation structure comprises a conductive structure and a top structure stacked in sequence; the conductive structure protrudes from the pixel definition layer and surrounds the plurality of pixel openings; the top structure is disposed on an upper surface of the conductive structure, covering the conductive structure and extending from the conductive structure in a direction parallel to the pixel definition layer.

15. The display panel according to claim 14, wherein in a direction perpendicular to the drive substrate, a longitudinal cross-section of a side wall of the conductive structure is trapezoidal, and traverse cross-sections of the side wall of the conductive structure gradually decrease in size toward the top structure.

16. The display panel according to claim 13, wherein the display panel is in a top-emitting mode, a thickness of the cathode in a direction perpendicular to the drive substrate is in a range from 5 nm to 50 nm, and a thickness of each anode is not less than 100 nm in the direction perpendicular to the drive substrate; or
the display panel is in a bottom-emitting mode, a thickness of each anode in a direction perpendicular to the drive substrate is in a range from 5 nm to 50 nm, and a thickness of the cathode in the direction perpendicular to the drive substrate is not less than 100 nm.

17. A display panel, manufactured by a manufacturing method comprising:
providing a preformed plate; wherein the preformed plate comprises a drive substrate, anodes, a pixel definition layer, and conductive isolation structures; the anodes and the pixel definition layer are disposed on the drive substrate, the pixel definition layer defines a plurality of pixel openings, and the anodes are disposed within the plurality of pixel openings in a one-to-one correspondence; the conductive isolation structures protrude from the pixel definition layer and surrounds the plurality of pixel openings; and
depositing and forming a light-emitting layer and a cathode on the preformed plate in sequence; wherein in each pixel opening, a corresponding anode, the light-emitting layer, and the cathode are sequentially stacked to constitute a corresponding subpixel unit, and the cathode is in contact with and electrically connected to at least corresponding one of the conductive isolation structures;
wherein the depositing and forming a light-emitting layer and a cathode on the preformed plate in sequence comprises in sequence:
depositing and forming the light-emitting layer on the preformed plate;
vapor-depositing and forming a barrier layer on the light-emitting layer on a position except a region of a target pixel opening by means of a mask plate; wherein the barrier layer is mutually repulsive with a material of the cathode to prevent the material of the cathode from being deposited in a region of a non-target pixel opening; wherein one of the plurality of pixel openings is defined as the target pixel opening, and remaining of the plurality of pixel openings is defined as the non-target pixel opening;
depositing and forming the cathode on the light-emitting layer; and
removing the light-emitting layer on the position except the region of the target pixel opening, and removing the barrier layer on at least a part of the position except the region of the target pixel opening.

18. The display panel according to claim 17, wherein the depositing and forming a light-emitting layer and a cathode on the preformed plate in sequence is to prepare and form a first subpixel unit, and the method further comprises:
repeating the depositing and forming a light-emitting layer and a cathode on the preformed plate in sequence to prepare and form a second subpixel unit; wherein the first subpixel unit and the second subpixel unit are with different emitting colors;
wherein during the depositing and forming the light-emitting layer and the cathode on the preformed plate in sequence to prepare and form the first subpixel unit, one of the plurality of pixel openings corresponding to the first subpixel unit is defined as the target pixel opening; during the depositing and forming the light-emitting layer and the cathode on the preformed plate in sequence to prepare and form the second subpixel unit, one of the plurality of pixel openings corresponding to the second subpixel unit is defined as the target pixel opening.

19. The display panel according to claim 17, wherein the removing the light-emitting layer on the position except the region of the target pixel opening, and removing the barrier layer on at least a part of the position except the region of the target pixel opening comprise:
preparing a protective layer on a side of the cathode from the drive substrate;
preparing an anti-etching layer within the target pixel opening;
removing the protective layer, the barrier layer, and the light-emitting layer on the position except the region of the target pixel opening via etching; and
removing the anti-etching layer via etching.

20. A display device, comprising a circuit board and the display panel according to claim 13; wherein the circuit board is electrically coupled to the display panel.
